(19) United States
(12) Patent Application Publication
(10) Pub. No.: US 2015/0115316 A1
(43) Pub. Date: Apr. 30, 2015

(54) SEMICONDUCTOR DEVICE

(71) Applicant: DENSO CORPORATION, Kariya-city, Aichi-pref. (JP)

(72) Inventors: Kazuhiro Oyama, Nishitokyo-city (JP); Masakiyo Sumitomo, Okazaki-city (JP); Yasushi Higuchi, Okazaki-city (JP)

(21) Appl. No.: 14/391,197

(22) PCT Filed: Apr. 17, 2013
(86) PCT No.: PCT/JP2013/002598

§ 371 Date: Oct. 8, 2014

(30) Foreign Application Priority Data
May 7, 2012 (JP) 2012-106013

(51) Int. Cl. H01L 27/07; H01L 29/739; H01L 29/861

(52) U.S. Cl. CPC H01L 27/0722; H01L 29/861; H01L 29/7397
USPC 257/140

(57) ABSTRACT

A semiconductor device includes: a drift layer having a first conduction type; a base layer having a second conduction type and formed on the drift layer; an emitter layer having the first conduction type and formed in a surface layer portion of the base layer; a buffer layer having the first conduction type and formed in the drift layer separated from the base layer; a collector layer having the second conduction type and formed selectively in the buffer layer; a gate insulation film in contact with a channel region of the base layer between the drift layer and the emitter layer; a gate electrode formed on the gate insulation film; a first electrode electrically connected to the base layer and the emitter layer; and a second electrode electrically connected to the buffer layer and the collector layer. The buffer layer has a carrier density smaller than a space charge density.

### CROSS REFERENCE TO RELATED APPLICATION

This application is based on Japanese Patent Application No. 2012-106013 filed on May 7, 2012, the disclosure of which is incorporated herein by reference.

### TECHNICAL FIELD

The present disclosure relates to a semiconductor device (RC-IGBT) for performing two functions of an insulated gate bipolar transistor (hereinafter simply referred to as “IGBT”) and a free wheel diode (hereinafter simply referred to as “FWD”) with one element, which is formed on a common semiconductor substrate.

### BACKGROUND ART

A semiconductor device (RC-IGBT) in which one element is formed on a common semiconductor substrate in such a way as to perform the function of a IGBT and the function of a FWD is proposed up to now as a semiconductor device that constructs an inverter circuit for driving the load of a motor or the like. Specifically, this semiconductor device has an NMOS structure formed on an obverse side of a drift layer of an N⁻ type, the NMOS structure being constructed of a base layer of a P type, an emitter layer of an N⁺ type, a gate structure, and an emitter electrode. The drift layer has a buffer layer of an N type formed on a reverse side thereof and the buffer has a collector layer of a P type selectively formed on a side opposite to the drift layer side thereof. Further, the semiconductor device has a collector electrode formed therein, the collector electrode being electrically connected to the collector layer and the buffer layer.

In this semiconductor device, when a specified electric potential is applied to a gate electrode of a gate structure, a channel region of the N type is formed in a base layer. Electrons are supplied to the drift layer via the channel region from an emitter electrode and the electrons supplied to the drift layer flow to a collector electrode via the buffer layer. The collector layer and the buffer layer are made to develop a short circuit by the collector electrode. This is because the buffer layer is the N type whereas the collector layer is the P type. When the electrons pass through the buffer layer, a voltage drop is caused by the resistance of the buffer layer. When the caused voltage drop is not less than a built-in voltage of a PN junction constructed between the collector layer and the buffer layer, holes are injected into the buffer layer from the collector layer. Then, the injected holes are supplied to the drift layer to thereby modulate the conductivity of the drift layer. In this way, voltage V_{CE} to be applied between the collector electrode and the emitter electrode is made smaller, whereby the IGBT is brought into an ON state.

For this reason, in order to bring the IGBT of this semiconductor device (RC-IGBT) into the ON state to produce a low voltage V_{CE}, there is required an electron current large enough to make a voltage, which is to be applied to the PN junction constructed of the collector layer and the buffer layer, the built-in voltage. In other words, in the case where only an electron current insufficient for making the voltage the built-in voltage flows, a conductivity modulation is not developed and hence the voltage V_{CE} is held large.

This means that the semiconductor device (RC-IGBT) has a currentvoltage characteristic (I-V characteristic) to be shown below. That is, when a collector current I_{c} is 0 A, the voltage V_{CE} is 0 V, and the voltage V_{CE} becomes large in a region in which the corrector current I_{c} is small. When the electron current becomes more than the collector current I_{c} sufficient for developing the conductivity modulation, the voltage V_{CE} abruptly becomes small.

This phenomenon is usually called a snapback phenomenon and is not desired practically. In this regard, as the collector current I_{c} is made larger, the voltage V_{CE} is abruptly made small, and a maximum value of the voltage V_{CE} just before the voltage V_{CE} being abruptly made small is called a snapback voltage.

For this reason, for example, in the patent documents 1 to 3 is proposed a structure for preventing a snapback phenomenon in a semiconductor device in which one element performing the function of the IGBT and the function of the FWD is formed on a common semiconductor substrate.

Specifically, in the patent document 1 is disclosed the following technique: that is, when an electric resistivity of a drift layer is assumed to be ρ1 (Ω·cm) and a thickness of the drift layer is assumed to be L1 (μm) and an electric resistivity of a buffer layer is assumed to be ρ2 (Ω·cm) and a thickness of the buffer layer is assumed to be L2 (μm) and ½ of a minimum width in a direction of a substrate plane of a collector layer is assumed to be W2 (μm), a semiconductor device is constructed in such a way as to satisfy the following formula (mathematical formula 1).

(ρ1/ρ2)×(L1×L2/W2²)<1.6

Further, in the patent document 2 is proposed a semiconductor device in which a barrier layer of a p type, which has an opening formed just above a collector layer, is formed on a drift layer side in a buffer layer.

According to this, electrons are constricted by the opening, whereby the electrons can be constricted in a region between the barrier layer and the collector layer in the buffer layer. In this way, a voltage drop developed by the electrons can be made larger and hence the development of the snapback phenomenon can be reduced. In other words, a snapback voltage can be reduced.

Still further, proposed in the patent document 3 is a semiconductor device which has many linear gate electrodes and in which when a direction parallel to a face direction in a face opposite to a drift layer of a buffer layer is assumed to be an X-Y direction, a cathode layer (buffer layer) is distributed in a nearly uniform XY lattice and a lattice constant in a Y direction is made longer than a lattice constant in an X direction parallel to the linear gate electrodes.

However, the semiconductor devices proposed in the patent documents 1 to 3 present the following problems. That is, an effective means for reducing a conduction loss when the IGBT is on is to reduce the thickness of the drift layer. In order to prevent a depletion layer from reaching the collector layer when the IGBT is off, there can be thought a structure in which: an impurity density of the buffer layer is increased; and the drift layer is thinned to thereby compensate lost space charges. In this case, for example, in the case where the buffer layer is doped with an impurity such as phosphorous, arsenic, or antimony, which is an ordinary donor, when a space charge density is increased, a carrier density is increased just like the space charge density and hence the resistance value of the drift layer is reduced.

Hence, in order to reduce the conduction loss of the IGBT and to prevent the snapback phenomenon, for example, by increasing the width of the collector layer and by elongating a course in which the electrons pass, a voltage drop caused by the electrons needs to be increased.

However, in this structure, the width of the collector layer is increased, so that of a PN junction constructed between the collector layer and the buffer layer, a region in which only voltage not larger than a built-in voltage is applied is increased. That is, a PN junction into which holes are injected is narrowed as compared to the whole PN junction constructed between the collector layer and the buffer layer. An interval between the PN junctions into which the holes are injected and which are adjacent to each other is increased. Hence, there is presented a problem that a large deviation is caused in the distribution of a carrier density (operating holes and electrons) to cause a current constriction, which results in presenting a problem that the element is easily broken. Further, since the region of the PN junction into which the holes are injected is narrowed, there is presented also a problem that an effective area functioning as the IGBT is narrowed to increase the conduction loss of the IGBT.

Further, when the FWD is on, the electrons are injected into the drift layer from the buffer layer (cathode layer) of a portion in contact with the collector electrode and the holes are injected from the base layer positioned on an obverse side of the drift layer.

In this case, in the semiconductor device described above, the width of the collector layer is increased and hence when the FWD is operated, a region into which the electrons are not injected is enlarged. That is, an effective area functioning as the FWD is decreased, which presents a problem that the conduction loss of the FWD is increased. A large deviation is caused also in the distribution of the carrier density of the operating FWD to cause a current constriction, which results in presenting also a problem that the element is easily broken.

Further, in order to reduce the conduction loss of the IGBT and to prevent the snapback phenomenon, it can be also thought that the resistance value of the buffer layer is increased. According to this thought, the resistance value of the buffer layer is increased and hence a voltage drop caused by the electrons can be increased, which eliminates the need for increasing the width of the collector layer. Hence, the conduction loss of the IGBT and the conduction loss of the FWD can be reduced and the snapback phenomenon can be prevented at the same time.

However, in the case where the buffer layer is doped with the impurities such as phosphorous, arsenic, or antimony, which is an ordinary donor, to construct the buffer layer having a small resistance value, this results in simply decreasing the impurity density of the buffer layer. In this case, when a reverse voltage is applied to the PN junction constructed of the base layer and the drift layer in an off state, even if a low reverse voltage is applied to the PN junction, the depletion layer reaches the collector layer, which results in increasing a leak current. In short, there is presented a problem that a rejection voltage (withstand voltage) is reduced. In this regard, the off state means a state where both of the IGBT and the FED are not on and a case where the collector electrode has a higher electric potential applied thereto as compared with the emitter electrode and where the gate electrode has an electric potential applied thereto, the electric potential being lower than a specified threshold potential.

As described above, all problems (items) of the snapback phenomenon, the conduction losses of the IGBT and the FWD, the current constriction, and the reduction in the withstand voltage are in a trade-off relationship. In the semiconductor devices of the patent documents 1 to 3, the trade-off relationship between some of the items may be improved but there is presented a problem that the trade-off relationship among all items cannot be improved at the same time.

### PRIOR ART LITERATURES

### Patent Literature

Patent document 1: JP-A 2007-288158
Patent document 2: JP-A 2011-114027
Patent document 3: JP-A 2011-155092

### SUMMARY OF INVENTION

It is an object of the present disclosure to provide a semiconductor device capable of improving all items of a snapback phenomenon, conduction losses of an IGBT and a FWD, a current constriction, and a reduction in a withstand voltage at the same time in the semiconductor device formed on a common semiconductor substrate in such a way as to have two functions of an IGBT and an FWD.

A semiconductor device includes: a drift layer having a first conduction type; a base layer having a second conduction type and formed in a surface layer portion of the drift layer; an emitter layer having the first conduction type and formed in a surface layer portion of the base layer; a buffer layer having the first conduction type and formed at a position of the drift layer separated from the base layer; a collector layer having the second conduction type and formed selectively in the buffer layer; a gate insulation film in contact with a channel region that is a portion of the base layer sandwiched between the drift layer and the emitter layer; a gate electrode formed on the gate insulation film; a first electrode electrically connected to the base layer and the emitter layer; and a second electrode electrically connected to the buffer layer and the collector layer. The buffer layer has a carrier density smaller than a space charge density.

In the semiconductor device described above, even if the space charge density of the buffer layer is increased, the resistance value can be prevented from being decreased. For this reason, even if the semiconductor device is constructed in such a way as to have the drift layer thinned so as to prevent the conduction loss of the IGBT and to have a large space charge density so as to prevent a depletion layer from reaching the collector layer, the semiconductor can have the resistance value of the buffer layer increased as compared with a conventional semiconductor device. In short, it is possible to reduce the conduction loss of the IGBT and to prevent the snapback phenomenon at the same time and in addition to prevent also a reduction in the withstand voltage. Further, the width of the collector layer does not need to be increased and hence the conduction loss and the current constriction can be prevented. That is, the trade-off relationship among all items of the snapback phenomenon, the conduction loss of the IGBT and the conduction loss of the FWD, the current constriction, and the reduction in the withstand voltage can be improved at the same time.

Alternatively, the buffer layer provides a level in a frozen region and a level in an extrinsic region. According to this mode, the temperature dependence of the resistance value of the buffer layer can be reduced.

### BRIEF DESCRIPTION OF DRAWINGS

The above and other objects, features and advantages of the present disclosure will become more apparent from the following detailed description made with reference to the accompanying drawings. In the drawings:

FIG. 1 is a view to show a section construction of a semiconductor device according to a first embodiment of the present disclosure; and

FIG. 2 is a view to show a section construction of a semiconductor device according to a third embodiment of the present disclosure.

### EMBODIMENTS FOR CARRYING OUT INVENTION

### First Embodiment

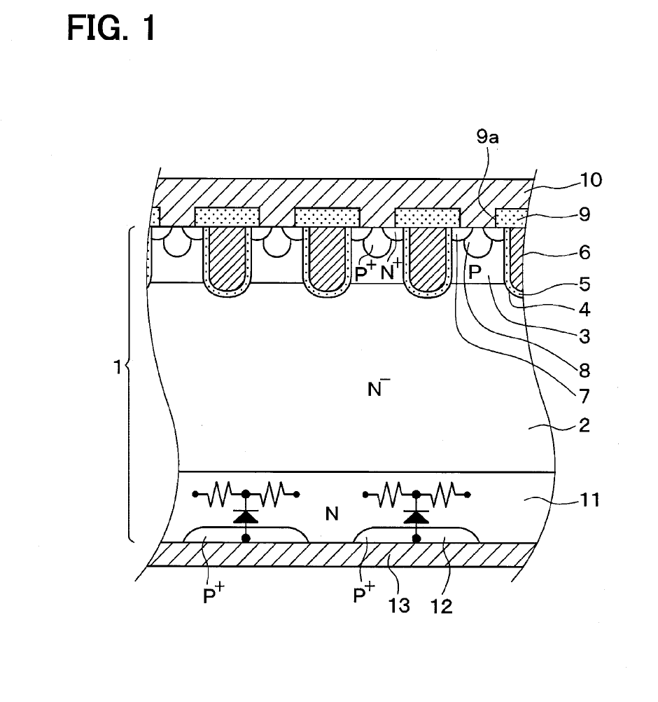

A first embodiment of the present disclosure will be described with reference to the drawing. As shown in FIG. 1, in a semiconductor device of the present embodiment, one element formed on a common semiconductor substrate 1 is formed in such a way as to have two functions of an IGBT and an FWD.

Specifically, the semiconductor substrate 1 has a drift layer 2 of an N⁻ type. A base layer 3 of a P type is formed on a surface layer portion of the drift layer 2. A plurality of trenches 4, which pass through the base layer 3 and reach the drift layer 2, are formed in a stripe pattern in a specified direction (in the present embodiment, in a direction vertical to the plane of paper). Each of these trenches 4 has a gate insulation film 5 and a gate electrode 6 formed in this order on a side wall thereof, the gate insulation film 5 being made of a thermal oxide film or the like, the gate electrode 6 being made of a doped Poly-Si or the like. That is, there is formed a trench gate structure made of the trench 4, the gate insulation film 5, and the gate electrode 6.

In this regard, when a specified electric potential is applied to the gate electrode 6, a channel region which will become an inversion layer is formed in a portion in contact with the trench 4 of the base layer 3, which will be specifically described later. In the present embodiment, a surface of the portion in contact with the wall surface of the trench 4 of the base layer 3 corresponds to a surface of the channel region.

Further, the base layer 3 has an emitter layer 7 of the N⁺ type formed on a surface layer thereof in such a way as to be in contact with a side face of the trench 4 and has a body layer 8 of a P⁺ type formed at a position separate from the side face of the trench 4. Specifically, the emitter layer 7 is formed in a structure in which the emitter layer 7 is extended in the shape of a bar in such a way as to be in contact with the side face of the trench 4 along a length direction of the trench 4 and in which the emitter layer 7 has its tip ended inside a tip of the trench 4. Still further, the body layer 8 is formed in a structure in which the body layer 8 is extended in the shape of a bar sandwiched between two emitter layers 7 and along the length direction of the trench 4 (in other words, along the emitter layers 7) and in which the body layer 8 has its tip ended inside the tip of the trench 4. Each of the emitter layers 7 and the body layer 8 is made higher in the density of impurities than the base layer 3 and is formed in a structure in which its tip is ended within the base layer 3.

In this regard, the base layer 3 and the body layer 8 are doped with an impurity, for example, boron or the like, and the emitter layer 7 is doped with an impurity, for example, phosphorous, arsenic, and antimony, or the like. That is, each of the base layer 3, the emitter layer 7, and the body layer 8 is made to have a level to show an activity rate of 100% at an operating temperature (for example, −40 to 150° C.) of the semiconductor device, in other words, a level positioned in an extrinsic region. Usually, it may be not clearly described in a semiconductor field that a level to show an activity rate of 100% is used, but this is omitted because this is a common sense in the semiconductor field.

An interlayer insulator 9 constructed of BPSG (Boron Phosphorous Silicon Glass) or the like is formed on the base layer 3. The interlayer insulator 9 has a contact hole 9a formed therein, whereby a portion of the emitter layer 7 and the body layer 8 are exposed from the interlayer insulator 9. The interlayer insulator 9 has an emitter electrode 10 formed thereon and the emitter electrode 10 is electrically connected to the emitter layer 7 and the body layer 8 (base layer 3) via the contact hole 9a.

Further, the drift layer 2 has a buffer layer 11 of an N type formed on a reverse face side thereof. Here, the construction of the buffer layer 11 of the present embodiment will be specifically described.

In the buffer layer 11 of the present embodiment, a carrier density is made smaller than a space charge density. That is, the activation energy of the level in the buffer layer 11 is made larger than the thermal energy of the operating temperature at the operating temperature of the semiconductor device. In other words, the buffer layer 11 is made to have a deep level to show an activity rate less than 100% at the operating temperature of the semiconductor device. Further, in other words, the buffer layer 11 is made to have a level positioned in a frozen region at the operating temperature of the semiconductor device. This buffer layer 11 is doped with at least one of impurities, for example, Bi, Mg, Ta, Pb, Te, Se, N, C, Ge, Sr, Cs, Ba, and S.

In this regard, the level of the buffer layer 11 in the present embodiment is a level in which a part of the buffer layer works as a carrier. That is, the level of the buffer layer 11 is different from a level, a so-called life time killer, which is positioned near a Mid Gap formed so as to shorten the life time of a small number of carriers. Further, the level of the buffer layer 11 is different from a comparatively deep level of C, Fe, or the like which compensates many carriers used in a HFET or the like of GaN or the like.

Further, the buffer layer 11 has a collector layer 12 of a P⁺ type selectively formed on a side opposite to the drift layer 2 side thereof. That is, the side opposite to the drift layer 2 side of the buffer 11 is constructed in such a way that, in a section shown in FIG. 1, the buffer layer 11 and the collector layer 12 are alternately arranged. On the side opposite to the drift layer 2 side of the buffer layer 11, a collector electrode 13 is formed in such a way that the collector layer 12 and the buffer layer 11 develop a short circuit.

The semiconductor device according to the present embodiment is constructed in the manner described above. In this regard, in the present embodiment, the N type corresponds to a first conduction type of the present disclosure and the P type corresponds to a second conduction type of the present disclosure. Further, the emitter electrode 10 corresponds to a first electrode of the present disclosure and the collector electrode 13 corresponds to a second electrode of the present disclosure.

Next, the action of the above-mentioned semiconductor will be described. First, an action when the semiconductor device turns on the IGBT will be described.

When a specified electric potential is applied to the gate electrode 6 in the semiconductor device described above, a channel region of the N type is formed at a portion in contact with the gate insulation film 5 arranged in the trench 4 of the base layer 3. Then, when voltage V_{CE} is applied between the collector electrode—the emitter electrode in such a way that the collector electrode 13 is higher in the electric potential than the emitter electrode 10, electrons flow from the emitter electrode 10 to the emitter layer 7, the channel region, the drift layer 2, the buffer layer 11, and the second electrode 13.

In this case, the buffer layer 11, as described above, is constructed in such a way that the carrier density is made smaller than the space charge density, so that even if the space charge density of the buffer layer 11 is made large, the carrier density of the buffer layer 11 can be prevented from becoming larger. That is, the resistance value of the buffer layer 11 can be made larger. Hence, a voltage drop when the electrons flow from the buffer layer 11 to the second electrode 13 can be made larger, and the IGBT can be turned on with a snapback phenomenon being prevented.

Next, an off state of the semiconductor device will be described. The off state means a state in which neither the IGBT nor the FWD are turned on and a case where the collector electrode 13 has a higher electric potential applied thereto than the emitter electrode 10 and where the gate electrode 6 has an electric potential, which is lower than a specified threshold potential, applied thereto.

In this case, a reverse voltage is applied to a PN junction constructed of the base layer 3 and the drift layer 2, whereby a depletion layer is made wider. When the depletion layer reaches the buffer layer 11, the level of the buffer layer 11 in the depletion layer is made higher than a Fermi level and a space charge region is constructed in which a level of 100% is ionized, which can prevent a reduction in a withstand voltage (refer to, for example, Physics of Semiconductor Devices 3rd Edition, P. 136-139, by S. M. Sze and Kwok K. N G, A John Wiley & Sons, INC. 2007)

Subsequently, an action when the FWD is turned on will be described. When the gate electrode 6 has an electric potential, which is lower than a threshold potential, applied thereto and the collector electrode 13 has a lower electric potential applied thereto as compared with the emitter electrode 10, electrons are injected from a portion in contact with the buffer layer 11 of the collector electrode 13 and holes are injected from the emitter electrode 10, whereby the FWD is turned on. In this case, the buffer layer 11 is constructed as described above and the width of the collector layer 12 is not wide, so a conduction loss and a current constriction can be prevented. In this regard, in this state, the emitter electrode 10 corresponds to an anode electrode and the collector electrode 13 corresponds to a cathode electrode.

As described above, in the present embodiment, the buffer layer 11 is constructed in such a way that the carrier density is made smaller than the space charge density. For this reason, even if the space charge density of the buffer layer 11 is made large, a resistance value can be prevented from being made small. Hence, even if the semiconductor device is constructed in such a way that the drift layer 2 is made thin so as to prevent the conduction loss of the IGBT and that a space charge density is made large so as to prevent the depletion layer from reaching the collector layer 12, the semiconductor device can have the resistance value of the buffer layer 11 made larger than a conventional semiconductor device. In short, in the present embodiment, the conduction loss of the IGBT can be reduced and the snapback phenomenon can be prevented at the same time and, in addition, also a reduction in the withstand voltage can be prevented.

Further, the width of the collector layer 12 does not need to be made wide, so that also the conduction loss and the current concentration can be prevented.

In other words, in the semiconductor device of the present embodiment, a tradeoff relationship between all items such as the snapback phenomenon, the conduction losses of the IGBT and the FWD, the current constriction, and the reduction in the withstand voltage can be improved at the same time.

Further, as compared with a conventional semiconductor device having a barrier layer formed therein, the semiconductor described above can be manufactured only by changing the kind of impurity constructing the buffer layer 11, so that a manufacturing process is not increased and hence also a manufacturing cost is not increased.

### Second Embodiment

A second embodiment of the present disclosure will be described. The present embodiment has the construction of the buffer layer 11 changed as compared with the first embodiment. The other portion of the present embodiment is the same as the first embodiment and hence the description of the other portion of the present embodiment will be omitted here. In this regard, a section construction of the semiconductor device of the present embodiment is the same as FIG. 1.

The buffer layer 11 of the present embodiment is constructed of two kinds of levels which are different in depth. Specifically, the buffer layer 11 of the present embodiment is constructed of a level in a frozen region and a level in an extrinsic region at the operating temperature of the semiconductor device. In this regard, the level of the extrinsic region is constructed by doping the buffer layer 11 with phosphorous, arsenic, antimony, or the like.

According to this, the temperature dependence of the resistance value in the buffer layer 11 can be reduced. That is, the level in the frozen region has the carrier density greatly changed by the operating temperature of the semiconductor device. In other words, the resistance value of the buffer layer 11 is greatly changed by the operating temperature of the semiconductor device. For this reason, when the buffer layer 11 is constructed of only the level in the frozen region, for example, in the case where the activity rate of a lower limit temperature at the operating temperature of the semiconductor device is 1% and where the activity rate of an upper limit temperature at the operating temperature of the semiconductor device is 10%, the resistance value of the buffer layer 11 is changed by ten times at most within an operating temperature range.

However, for example, in the case where the buffer layer 11 is constructed in such a way that the ratio of an impurity density positioned at the level of the frozen region to an impurity density positioned at the level of the extrinsic region is 1:1, the total activity rate becomes 50.5% at the lower limit temperature and becomes 55% at the upper limit temperature. That is, a rate of change in the resistance value of the buffer layer 11 can be reduced to 1.09 times.

In this regard, it is preferable that the impurity density positioned at the level of the frozen region, the impurity density positioned at the level of the extrinsic region, and the ratio of these impurity densities are changed as required according to the use environment of the semiconductor device.

### Third Embodiment

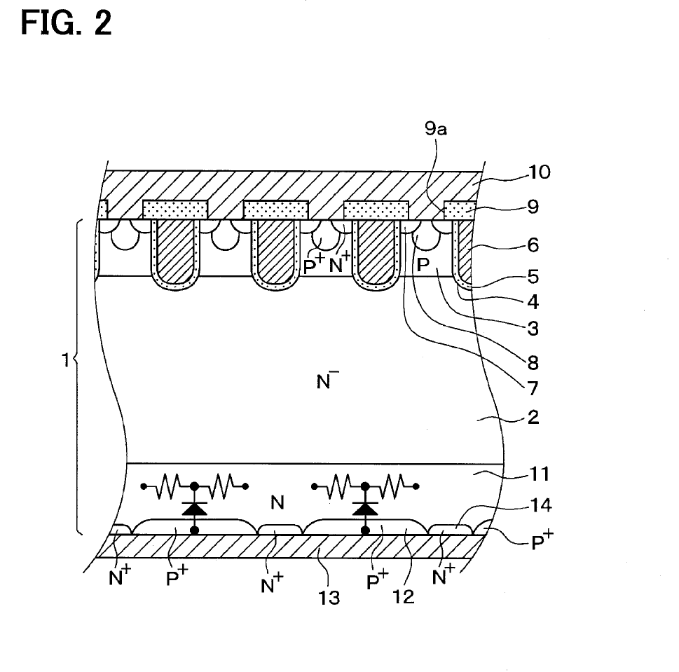

A third embodiment of the present disclosure will be described. The present embodiment has a cathode layer of an N⁺ type formed in the buffer layer 11 as compared with the first embodiment and is the same in the other portions as the first embodiment, so the description of the other portions will be omitted. FIG. 2 is a view to show a section construction of a semiconductor device according to the present embodiment.

As shown in FIG. 2, in the present embodiment, in a portion sandwiched by the collector layers 12 of the buffer layer 11 is formed a cathode layer 14 of an N⁺ type which has a carrier density made larger than the buffer layer 11. In other words, on a side opposite to the drift layer 2 side of the buffer layer 11 are alternately formed the collector layer 12 and the cathode layer 14. In this regard, for example, the cathode layer 14 is constructed by doping the buffer layer 11 with phosphorous, arsenic, antimony, or the like.

According to this, the contact resistance between the buffer layer 11 (cathode layer 14) and the collector electrode 13 can be reduced. Further, the carrier density (electron) of the cathode layer 14 is large, so that when the FWD is operated, electrons injected from the collector electrode 13 (cathode layer 14) can be increased. Hence, the conduction loss when the FWD is operated can be further reduced.

### Other Embodiments

In the respective embodiments described above, it is also recommended to make the first conduction type a P type and to make the second conduction type an N type. In this case, the buffer layer 11 is doped with at least one of impurities such as Ga, In, Ti, Be, Cu, Zn, Co, and the like. Further, it is also recommended to form the level of the buffer layer 11 by applying a thermal stress or a mechanical stress to the buffer layer 11 and by irradiating the buffer layer 11 with a proton beam, helium, tritium, or the like.

Further, in the respective embodiments described above haven been described the semiconductor devices having the IGBT of a trench gate type, but the semiconductor device can also have an IGBT of a planar gate type. In this case, although not shown especially, the emitter layer 7 and the body layer 8 are formed on the surface layer portion of the base layer 3, whereas the gate electrode 6 is formed on a portion, in which the emitter layer 7 and the body layer 8 are not formed, of the surface of the base layer 3 via the gate insulation film 5. For this reason, the portion, in which the emitter layer 7 and the body layer 8 are not formed, of the surface of the base layer 3 corresponds to the surface of the base layer 3 of the present disclosure.

Still further, in the respective embodiments described above haven been described the vertical type semiconductor devices in which current flows in a thickness direction of the drift layer 2, but a lateral type semiconductor device can be also formed in which current flows in a plane direction of the drift layer 2.

It is also recommended to employ a semiconductor device in which the second embodiment is combined with the third embodiment. That is, it is also recommended to construct the buffer layer 11 by the use of two different levels and to form the cathode layer 14 in a region sandwiched by the collector layers 12 of the buffer layer 11.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

1. A semiconductor device comprising:
a drift layer having a first conduction type;
a base layer having a second conduction type and formed in a surface layer portion of the drift layer;
an emitter layer having the first conduction type and formed in a surface layer portion of the base layer;
a buffer layer having the first conduction type and formed at a position of the drift layer separated from the base layer;
a collector layer having the second conduction type and formed selectively in the buffer layer;
a gate insulation film in contact with a channel region that is a portion of the base layer sandwiched between the drift layer and the emitter layer;
a gate electrode formed on the gate insulation film;
a first electrode electrically connected to the base layer and the emitter layer; and
a second electrode electrically connected to the buffer layer and the collector layer,
wherein the buffer layer has a carrier density smaller than a space charge density.

2. The semiconductor device according to claim 1,
wherein the buffer layer provides a level in a frozen region.

3. The semiconductor device according to claim 1,
wherein the buffer layer provides a level in a frozen region and a level in an extrinsic region.

4. The semiconductor device according to claim 1,
wherein the collector layer includes a plurality of collector portions, and
wherein the buffer layer has a cathode layer, which is arranged in a portion of the buffer layer between the plurality of collector portions, provides a level shallower than the buffer layer, and has a carrier density larger than the buffer layer.

5. The semiconductor device according to claim 1,
wherein the first conduction type is an N conductive type and the second conduction type is a P conductive type, and
wherein the buffer layer is doped with at least one of Bi, Mg, Ta, Pb, Te, Se, N, C, Ge, Sr, Cs, Ba, and S.

6. The semiconductor device according to claim 1,
wherein the first conduction type is an P conductive type and the second conduction type is an N conductive type, and
wherein the buffer layer is doped with at least one of Ga, In, Be, Cu, Zn, and Co.
